(19) United States
(12) Patent Application Publication
(10) Pub. No.: US 2005/0047984 A1
(43) Pub. Date: Mar. 3, 2005

(54) High-purity lithium carboxylate crystal, production method thereof and use thereof

(76) Inventors: Hiroshi Sakaguchi, Tsukuba-shi (JP); Shinsuke Yamazaki, Tsukuba-shi (JP); Yasuo Gama, Tsukuba-shi (JP)

Correspondence Address: BIRCH STEWART KOLASCH & BIRCH, PO BOX 747, FALLS CHURCH, VA, 22040-0747, US

(21) Appl. No.: 10/788,334

(22) Filed: Mar. 1, 2004

(30) Foreign Application Priority Data
Aug. 27, 2003 (JP) 2003-302605
Aug. 28, 2003 (JP) 2003-303866
Aug. 28, 2003 (JP) 2003-303935

(51) Int. Cl. C30B 1/00; C01B 33/26; C11D 3/00; C11D 7/18; C11D 7/54; C11D 9/42

(52) U.S. Cl. 423/328.2

(57) ABSTRACT

A lithium carboxylate crystal, which is obtained by: dissolving an aliphatic carboxylic acid, lithium hydroxide, and urea in water, to give a solution thereof, and crystallizing lithium carboxylate from the solution; a method of producing the lithium carboxylate crystal; and a method of solidifying a halogen-containing liquid organic compound or a gaseous hydrocarbon, by using the lithium carboxylate crystal.

### FIELD OF THE INVENTION

The present invention relates to a high purity crystal of lithium carboxylate, which lithium carboxylate is widely used in industrial fields such as plastics, paper and pulp, grease, metallurgy, casting, paint, rubber industry, and ceramics, and which may also be widely used in other industrial fields. The present invention also relates to a production method of the lithium carboxylate high-purity crystals.

Further, the present invention relates to a solidifying material composed of long-fibrous crystals of lithium carboxylate efficiently solidifying a halogen-containing liquid organic compound. Further, the present invention also relates to a method of solidifying the halogen-containing liquid organic compound, by using the solidifying material.

Furthermore, the present invention relates to a fixing material for a gaseous hydrocarbon, a production method of the same, and a method of solidifying the gaseous hydrocarbon. More specifically, the present invention relates to a fixing material for a gaseous hydrocarbon, by using long-fibrous crystals of lithium carboxylate, a production method of the same, and a method of solidifying the gaseous hydrocarbon by using the fixing material.

### BACKGROUND OF THE INVENTION

Carboxylates of metals other than sodium and potassium, so-called metal soaps, have been widely used for various applications such as a lubricant, a slip additive, a thickener, and a releasing agent in various industrial fields such as plastics, paper and pulp, grease, metallurgy, casting, paint, rubber industry, and ceramics. Those applications utilize properties of the metal soaps to have a molecular structure similar to a sodium soap and a potassium soap, in other words, a structure with a long-chain alkyl group and a metal bonding to a carboxyl group, and to stably maintain hydrophobicity for a long period of time because the metal soaps do not easily dissolve in water.

The property of being water-insoluble is the greatest characteristic of the metal soaps. However, this property has simultaneously inhibited production of a high-purity metal soap. Lithium carboxylate, having a long-chain alkyl group, substantially does not dissolve in water at a room temperature (25° C.) although lithium belongs to alkali metals as sodium and potassium. Pure crystals cannot be obtained by precipitating lithium carboxylate dissolved in water following the same technique as for the sodium and potassium soaps.

Primarily two methods, a direct method and a metathesis, are used for producing lithium carboxylate industrially. In both methods, the lithium carboxylate is synthesized from sodium carboxylate or carboxylic acid without being completely dissolved in a solvent such as an alcohol or water, thereby providing a powdery, gel product, or massive or aggregated product containing much impurities. High-purity lithium carboxylate is perceived to essentially have excellent and unique properties. However, characteristics of the high-purity lithium carboxylate are not sufficiently utilized, and its applications are probably yet limited (see, for example, “Kinzoku Sekken no Seishitsu to Ouyou (Properties and Applications of Metal Soaps)”, edited and written by Tokiyuki Yoshida, Shinichi Shindo, Tadayoshi Ogaki, and Kesaichi Ide, Saiwai shobo, 1988).

A method of producing high-purity lithium carboxylate of 95% or more purity as crystals having a crystalline structure instead of a powdery, gel product, aggregated precipitate is not yet put into practical use, and such method is hardly proposed even at an experimental stage. To produce high-purity lithium carboxylate crystals, the lithium carboxylate crystals formed must be completely dissolved in a solvent once, and then precipitated as crystals again. In each conventional, industrial production method for lithium carboxylate, the lithium carboxylate formed is separated as a precipitate as it is without being completely dissolved in a solvent. The precipitate is used as it is or used after being subjected to mechanical pulverization (see, the above-described “Kinzoku Sekken no Seishitsu to Ouyou”, for example).

A report exists describing an observation of lithium carboxylate, calcium carboxylate, or the like, under a very unusual condition, such as being precipitated in a grease or an alcohol, with an electron microscope, confirmed spiral, long-fibrous crystals (see, “Kagaku wo Tsukutteyuku Michisuji, V. Rasen to Busshitsul”, by Taro Tachibana, Kagaku-dojin Publishing Company, Inc., 1983, for example). From those results, it is impossible to industrially produce high purity crystals of lithium carboxylate.

Further, the scale of petrochemical industry and natural gas industry is enlarging year by year, and mass production and mass consumption of organic compounds including halogen-containing liquid organic compounds, are conducted. Along with those, occur, frequently worldwide, environmental pollution and accidents threatening the existence of human beings and living things: e.g. pollution in rivers, lakes, marshes, sea and soils, which are attributable to accidents in various chemical factories, petrochemical complexes, tankers, and the like; waste of industrial products; leakage in the time of storage; accumulation in environment, animals, plants, and human bodies; action thereof as toxic substance; fires and explosions. Accordingly, safe handling and suitable treating during transportation or storage of halogen-containing liquid organic compounds and gaseous hydrocarbons including petrochemical materials, are critical problems.

Generally, many of halogen-containing liquid organic compounds are deleterious, irritant, and toxic, and in addition, many also are flammable. Trihalomethane, such as chloroform, slightly dissolved in water is widely known to be deleterious to human body. Further, production and use of polychlorinated biphenyl (PCB), mass-produced for a period of time and widely used for large-scale transformers, heating mediums in a food oil production step, and household appliances, are prohibited worldwide now, and complete destruction thereof in the future is obligated. However, a long storage of the PCB as used is obliged because adequate washing means and separating means from appliances are not discovered. Nevertheless, leakage accidents, landfills, or the like of the PCB is reported in various regions.

Examples of fundamental measures against these many kinds of disasters, explosions, fires, leakage, and other accidents; and long-continuing progression and expansion of pollution include: that (1) halogen-containing liquid organic compound, and mixtures thereof are converted into safe solids enable easy storage and transportation, to assuredly process thereof through incineration or the like; and that (2) a large amount of gaseous hydrocarbon handled in various chemical facilities, petrochemical complexes and tankers, and mixtures thereof are converted into safe solids, and, if necessary, returned to the original gaseous one. It is thought that by conversion thereof into safe solids easy to handle, many accidents would be prevented; the solids could be processed assuredly; and huge and often dangerous storage facilities, pipelines, trucking, freezing or thermally insulating facilities could be significantly modified.

Further, it is extremely important to selectively solidify halogen-containing liquid organic compounds in factories or industrial products, and to separate and recover a small amount of the halogen-containing liquid organic compounds adhering to or remaining in a vessel or the like.

Further, selectively adsorbing and removing vapor vaporized from hydrocarbon in an exhaust gas or the like from productive facilities or the like of chemical factories and from liquid hydrocarbon are extremely important, in view of effective utilization of resources, prevention of air pollution, and prevention of danger such as explosion.

In consideration of these aspects, there is a demand for development of a method wherein gaseous hydrocarbon, low-boiling-point liquid hydrocarbon, hydrocarbon contained in exhaust gas, and the like handled in various chemical factories, petrochemical complexes and tankers, or a wide variety of halogen-containing liquid hydrocarbon existing in various forms, are solidified easily, converted into safe forms, and recovered assuredly; and then returned, if necessary, to the original hydrocarbons. Conversion of halogen-containing liquid organic compound and gaseous or liquid hydrocarbon into other safe materials by a certain chemical reaction possesses a danger to cause many secondary disasters in fact. Therefore, a method accompanying chemical reaction should be avoided.

Accordingly, a method of solidifying the above-mentioned various substances as they are by a physicochemical means is considered most preferable.

The requirements for a material solidifying for the halogen-containing liquid organic compound include: (1) the solidifying material can assuredly solidify and recover the halogen-containing liquid organic compound without remaining in the vessel used for storage, and solidified aggregates can be relatively easily and safely handled; (2) the solidifying material is chemically relatively stable; and (3) since the solidifying material is supposed to be used under various conditions and environments, the solidifying material is a safe and harmless substance, and even if the material flows out of an assumed region and is hardly recovered, the material itself is least dangerous for affecting to living things in the environment and to the environment per se.

On the other hand, the requirements for a fixing material for a gaseous hydrocarbon include, in addition to the above-described requirements (2) and (3), (4) the gaseous hydrocarbon can be fixed and solidified easily without damaging reaction units in a factory and the like, and from the solidified complex, the original gaseous hydrocarbon can be easily recovered, and further the recovered fixing material can be used through recycling.

Short-fibrous or long-fibrous sodium carboxylate and potassium carboxylate are proposed for such a physicochemical collecting material (for example, see JP-A-2002-273217 (“JP-A” means unexamined published Japanese patent application) and JP-A-2002-273216). Those short fibrous or long fibrous sodium carboxylate and potassium carboxylate are confirmed to possess exceptional collecting ability for organic compound, such as liquid hydrocarbon and gaseous hydrocarbon; and to stably collect a large amount of the hydrocarbon. However, those fibrous sodium or potassium carboxylates also have a room for further improvement, in such points that an effective carbon chain length thereof and an effective salt concentration thereof in an aqueous solution are limited because of relatively large solubility to water of those fibrous sodium or potassium carboxylates. Further, those fibers very stably retain their functions for a long time in a dispersed form in water. However, in some cases, a stable form changes from fibrous crystals to plate-like crystals in a dry state, resulting in a problem such as conspicuously degrading the collecting ability for the organic compound such as liquid hydrocarbon and gaseous hydrocarbon.

Notably, when collecting and solidifying a halogen-containing liquid organic compound, an amount of water to be used is desirably as reduced as possible, because the water used for the solidification is also at risk of becoming polluted by the halogen-containing liquid organic compound.

Further, halogen-containing liquid organic compounds generally have a property of higher density than water, unlike usual hydrocarbons. Therefore, many thereof sink to a bottom of water when mixed with the water. Nevertheless, the halogen-containing liquid organic compound mixes well with usual hydrocarbon. Therefore, high density halogen-containing liquid organic compound sunk to the bottom of the water must be solidified if the compound is used alone, and the halogen-containing liquid organic compound existing above water or below water depending on a mixing ratio with the hydrocarbon must be collected and solidified if the compound is used in a mixture. The more effective collecting and solidifying material for a halogen-containing liquid organic compound, which resolves those problems described above, is not yet put into practical use, and such material is hardly proposed even at an experimental stage.

### SUMMARY OF THE INVENTION

The present invention resides in a lithium carboxylate crystal, which is obtained by dissolving an aliphatic carboxylic acid, lithium hydroxide, and urea in water, to give a solution thereof, and then crystallizing lithium carboxylate from the solution; and a producing method thereof.

Further, the present invention resides in a lithium carboxylate crystal, which is obtained by dissolving an aliphatic carboxylic acid, lithium hydroxide, urea and lithium chloride in water, to give a solution thereof, and then crystallizing lithium carboxylate from the solution; and a producing method thereof.

Further, the present invention resides in a lithium carboxylate crystal, which is obtained by dissolving an aliphatic sodium carboxylate and/or an aliphatic potassium carboxylate, lithium chloride, and urea in water, to give a solution thereof, and then crystallizing lithium carboxylate from the solution; and a producing method thereof.

Further, the present invention resides in a solidifying material for a halogen-containing liquid organic compound, which comprises lithium carboxylate long-fibrous crystals; in which the lithium carboxylate long-fibrous crystals are obtained by dissolving an aliphatic carboxylic acid, lithium hydroxide, and urea in water, to give a solution thereof, and then crystallizing lithium carboxylate from the solution.

Further, the present invention resides in a solidifying material for a halogen-containing liquid organic compound, which comprises lithium carboxylate long-fibrous crystals; in which the lithium carboxylate long-fibrous crystals are obtained by dissolving an aliphatic carboxylic acid, lithium hydroxide, urea, and lithium chloride in water, to give a solution thereof, and then crystallizing lithium carboxylate from the solution.

Further, the present invention resides in a solidifying material for a halogen-containing liquid organic compound, which comprises lithium carboxylate long-fibrous crystals; in which the lithium carboxylate long-fibrous crystals are obtained by dissolving an aliphatic sodium carboxylate and/or an aliphatic potassium carboxylate, lithium chloride, and urea in water, to give a solution thereof, and then crystallizing lithium carboxylate from the solution.

Further, the present invention resides in a fixing material for a hydrocarbon that is gaseous at 20° C. and 0.1 MPa, in which the fixing material is obtained by the steps of dissolving a carboxylic acid, lithium hydroxide, and urea in water to give a solution thereof, gradually cooling the solution, and then precipitating long fibrous crystals from the solution; and a producing method thereof.

Further, the present invention resides in a fixing material for a hydrocarbon that is gaseous at 20° C. and 0.1 MPa, in which the fixing material is obtained by the steps of completely dissolving a sodium carboxylate and/or a potassium carboxylate, and urea in water to give a solution, adding to the solution an aqueous lithium chloride solution, gradually cooling the resulting solution, and then precipitating long fibrous crystals from the solution; and a producing method thereof.

Other and further features and advantages of the invention will appear more fully from the following description, taken in connection with the accompanying drawing.

### BRIEF DESCRIPTION OF THE DRAWING

FIG. 1 is an optical microscope photograph showing one example of the long-fibrous lithium laurate crystals obtained by the method of the present invention.

### DETAILED DESCRIPTION OF THE INVENTION

According to the present invention, there are provided the following means:
(1) A lithium carboxylate crystal, which is obtained by: dissolving an aliphatic carboxylic acid, lithium hydroxide, and urea in water, to give a solution thereof; and crystallizing lithium carboxylate from the solution;
(2) A lithium carboxylate crystal, which is obtained-by: dissolving an aliphatic carboxylic acid, lithium hydroxide, urea, and lithium chloride in water, to give a solution thereof; and crystallizing lithium carboxylate from the solution;
(3) A lithium carboxylate crystal, which is obtained by: dissolving at least one carboxylate selected from the group consisting of aliphatic sodium carboxylates and aliphatic potassium carboxylates, lithium chloride, and urea in water, to give a solution thereof; and crystallizing lithium carboxylate from the solution;
(4) The lithium carboxylate crystal according to any one of the above items (1) to (3), wherein the lithium carboxylate crystal has high purity;
(5) A method of producing a lithium carboxylate crystal, comprising the steps of:
   dissolving an aliphatic carboxylic acid, lithium hydroxide, and urea in water, to give a solution thereof; and
   crystallizing lithium carboxylate from the solution;
(6) The method according to the above item (5), wherein, in the dissolving step, lithium chloride is added in the water, to dissolve the aliphatic carboxylic acid, lithium hydroxide, and urea;
(7) A method of producing a lithium carboxylate crystal, comprising the steps of:
   dissolving at least one carboxylate selected from the group consisting of aliphatic sodium carboxylates and aliphatic potassium carboxylates, lithium chloride, and urea in water, to give a solution thereof; and
   crystallizing lithium carboxylate from the solution;
(8) The method according to any one of the above items (5) to (7), wherein the lithium carboxylate crystal has high purity;
   (Hereinafter, a first embodiment of the present invention means to include the lithium carboxylate crystals described in the items (1) to (4) above, and the production methods described in the items (5) to (8) above.)
(9) A solidifying material for a halogen-containing liquid organic compound, comprising lithium carboxylate long-fibrous crystals;
   wherein the lithium carboxylate long-fibrous crystals are obtained by: dissolving an aliphatic carboxylic acid, lithium hydroxide, and urea in water, to give a solution thereof; and crystallizing lithium carboxylate from the solution;
(10) A solidifying material for a halogen-containing liquid organic compound, comprising lithium carboxylate long-fibrous crystals;
   wherein the lithium carboxylate long-fibrous crystals are obtained by: dissolving an aliphatic carboxylic acid, lithium hydroxide, urea, and lithium chloride in water, to give a solution thereof; and crystallizing lithium carboxylate from the solution;
(11) A solidifying material for a halogen-containing liquid organic compound, comprising lithium carboxylate long-fibrous crystals;
   wherein the lithium carboxylate long-fibrous crystals are obtained by: dissolving at least one carboxylate selected from the group consisting of aliphatic sodium carboxylates and aliphatic potassium carboxylates, lithium chloride, and urea in water, to give a solution thereof; and crystallizing lithium carboxylate from the solution;
(12) A method of solidifying a halogen-containing liquid organic compound, comprising:
   solidifying the halogen-containing liquid organic compound, by using the solidifying material according to any one of the above items (9) to (11);
   (Hereinafter, a second embodiment of the present invention means to include the solidifying materials described in the items (9) to (11) above, and the solidifying method described in the item (12) above.)
(13) A fixing material for a hydrocarbon that is gaseous at 20° C. and 0.1 MPa,
   wherein the fixing material is obtained by the steps of: dissolving a carboxylic acid, lithium hydroxide, and urea in water, to give a solution; gradually cooling the solution; and precipitating crystals in a long fibrous shape from the solution;
(14) The fixing material according to the above item (13), wherein the fixing material is obtained by further dissolving lithium chloride in the water, in the dissolving step;
(15) A fixing material for a hydrocarbon that is gaseous at 20° C. and 0.1 MPa,
   wherein the fixing material is obtained by the steps of: completely dissolving at least one carboxylate selected from the group consisting of sodium carboxylates and potassium carboxylates, and urea in water, to give a solution; adding, to the solution, an aqueous lithium chloride solution; gradually cooling the solution; and precipitating crystals in a long fibrous shape from the solution;
(16) The fixing material according to any one of the above items (13) to (15),
   wherein the precipitated long-fibrous crystals are dried up;
(17) A method of solidifying a hydrocarbon that is gaseous at 20° C. and 0.1 MPa, comprising:
   solidifying the hydrocarbon, by using the fixing material according to any one of the above items (13) to (16);
(18) A method of solidifying a hydrocarbon that is gaseous at 20° C. and 0.1 MPa, comprising the steps of:
   solidifying the hydrocarbon, by using the fixing material according to any one of the above items (13) to (16); to give a solid aggregate;
   heating the solid aggregates, to decompose into lithium carboxylate crystals and the gaseous hydrocarbon;
   separating the lithium carboxylate crystals from the gaseous hydrocarbon; and
   recovering the lithium carboxylate crystals for recycling;
(19) A method of producing a fixing material for a hydrocarbon that is gaseous at 20° C. and 0.1 MPa, comprising the steps of:
   dissolving a carboxylic acid, lithium hydroxide, and urea in water, to give a solution;
   gradually cooling the solution; and
   precipitating crystals in a long fibrous shape from the solution;
(20) The method according to the above item (19), wherein the fixing material is obtained by further dissolving lithium chloride in the water, in the dissolving step; and
(21) A method of producing a fixing material for a hydrocarbon that is gaseous at 20° C. and 0.1 MPa, comprising the steps of:
   completely dissolving at least one carboxylate selected from the group consisting of sodium carboxylates and potassium carboxylates, and urea in water, to give a solution;
   adding, to the solution, an aqueous lithium chloride solution;
   gradually cooling the solution; and
   precipitating crystals in a long fibrous shape from the solution.

(Hereinafter, a third embodiment of the present invention means to include the fixing materials described in the items (13) to (16) above, the solidifying methods described in the items (17) to (18) above, and the production methods described in the items (19) to (21) above.)

Herein, the present invention means to include all of the above first, second and third embodiments, unless otherwise specified.

The present inventors have studied the synthesis, dissolution, emulsification and dispersion behavior, in water, of aliphatic carboxylic acids having alkyl groups of various lengths and lithium salts thereof. As a result, we have found that these aliphatic carboxylic acids and lithium salts thereof are dissolved completely in water at a high temperature by adding urea; solubility of these aliphatic carboxylic acids and lithium salts thereof can be adjusted by further adding lithium chloride as required; by stirring and gradually cooling the compounds in a completely dissolved state, the lithium carboxylates are precipitated, for the first time, as crystals having various forms, such as long fibrous crystals; a crystal form changes to the most stable, long fibrous crystals in many cases, by maintaining at room temperature (25° C.); crystals of extremely high purity can be provided by washing, filtering, and drying such crystals; the long fibrous crystals thus obtained can be stored for a long period of time without changing their crystalline forms, as extremely high purity crystals via purifying and drying; and these fibrous crystal aggregates particularly efficiently solidify various halogen-containing liquid organic compound and gaseous hydrocarbons. The present invention is accomplished by further studies based on these findings.

Herein, a “high purity” crystal refers to mean the crystal that precipitates in a clear crystalline form instead of as a powdery, gel-like, or aggregated precipitate. Further, the high purity crystal refers to mean the crystal containing 90 mass % or more, preferably 95 mass % or more, and particularly preferably 97 mass % or more of lithium carboxylate in the crystal after drying.

The high purity lithium carboxylate crystals of the present invention are in a long fibrous form in many cases, but may be in a rod-like, plate-like, or scaly form.

In the present invention, the “long-fibrous crystals” are aggregates of innumerable fine long-fibrous crystals, and the thickness of one long-fibrous crystal is preferably 5 μm or less. The length of one long-fibrous crystal is preferably 100 to 3,000 μm, more preferably 100 to 2,000 μm, further preferably 500 to 2,000 μm, and particularly preferably 500 to 1,000 μm. Further, one fibrous crystal is composed of a large number of finer fibrous crystals.

Further, herein, the halogen-containing liquid organic compound refers to mean a halogen-containing organic compound in the form of liquid at ordinary temperature (20° C.) at normal pressure (0.1 MPa), and the gaseous hydrocarbon refers to mean a hydrocarbon in the form of gas at 20° C. at 0.1 MPa.

Any water usually used may be employed for the water to be used in the present invention. Specific examples of the-water that can be used include distilled water, ion-exchange water, tap water, natural soft water, pure water, and ultrapure water. Of those, preferably employed is the soft water having a softness of the tap water or softer, more preferably pure water. Herein, in the present invention, the pure water means water that is not seawater and is preferably water substantially not containing any salt content.

Carboxylic acid, sodium carboxylate, or potassium carboxylate (hereinafter, these may be simply referred to as carboxylic acid or the like) that can be used in the present invention, preferably in the third embodiment for the production of the fixing material for a gaseous hydrocarbon, is preferably an aliphatic carboxylic acid, an aliphatic sodium carboxylate, or an aliphatic potassium carboxylate, and more preferably a compound of the structure having a straight alkyl chain of these, an aliphatic carboxylic acid or the like having a straight alkyl chain, is further preferable.

Hereinafter, aliphatic carboxylic acid, aliphatic sodium carboxylate, or aliphatic potassium carboxylate for use in the first and second embodiments of the present invention (hereinafter, these may be simply referred to as aliphatic carboxylic acid or the like), and the above carboxylic acid, sodium carboxylate, or potassium carboxylate for use in the third embodiment of the present invention (the above-described carboxylic acid or the like) may be referred to as “(aliphatic) carboxylic acid”, “(aliphatic) sodium carboxylate”, or “(aliphatic) potassium carboxylate”, respectively. In addition, these may be collectively referred to as “(aliphatic) carboxylic acid or the like”, for simplification of explanation.

In the present invention, the (aliphatic) carboxylic acid, the (aliphatic) sodium carboxylate, or the (aliphatic) potassium carboxylate used for producing high purity lithium carboxylate crystals (e.g., long fibrous crystals) can be completely dissolved in water by heating under stirring in the presence of urea (or alternatively in the absence of urea when using the (aliphatic) sodium carboxylate or (aliphatic) potassium carboxylate, in some cases). Further, lithium carboxylate crystals can be obtained by adding lithium hydroxide (or lithium chloride when using the (aliphatic) sodium carboxylate or (aliphatic) potassium carboxylate) to react and by gradually cooling with or without stirring.

A temperature to completely dissolve the (aliphatic) carboxylic acid, the (aliphatic) sodium carboxylate, or the (aliphatic) potassium carboxylate in water is generally 80 to 150° C., preferably 90 to 100° C., though depending on a length of an alkyl chain of the (aliphatic) carboxylic acid or the like and an amount of the urea, or the like.

Further, the temperature for reacting the solution prepared by completely dissolving the (aliphatic) carboxylic acid or the like in water as described above by adding lithium hydroxide (or lithium chloride when using the (aliphatic) sodium carboxylate or the (aliphatic) potassium carboxylate) is generally 80 to 150° C., preferably 90 to 100° C., though depending on an amount of the lithium hydroxide or the like. A reaction time thereof is generally 10 to 200 minutes, preferably 30 to 150 minutes.

In the present invention, preferably in the first and second embodiments of the present invention, the aliphatic carboxylic acid, the aliphatic sodium carboxylate, or the aliphatic potassium carboxylate used for producing the lithium carboxylate crystals of the present invention may have any alkyl chain of a straight-chain saturated chain, a straight-chain unsaturated chain, a branched saturated chain, or a branched unsaturated chain. Of these, preferable is one having a straight-chain alkyl chain, more preferable a straight-chain saturated alkyl chain.

Further, the carboxylic acid or the like, for example, aliphatic carboxylic acid, aliphatic sodium carboxylate or aliphatic potassium carboxylate, may be composed of any of monocarboxylic acid, dicarboxylic acid, or tricarboxylic acid, and preferably composed of monocarboxylic acid.

The (aliphatic) carboxylic acid, the (aliphatic) sodium carboxylate, or the (aliphatic) potassium carboxylate preferably has an appropriate length of the alkyl chain allowing: complete dissolution of the (aliphatic) carboxylic acid or the like in water, by adding lithium hydroxide in the case of (aliphatic) carboxylic acid or adding lithium chloride in the case of (aliphatic) sodium carboxylate or (aliphatic) potassium carboxylate, further adding an appropriate amount of urea, and heating; and precipitation as crystals, preferably crystallization as fibrous crystals, by stirring and gradual cooling.

Specifically, in the present invention, preferably in the first and second embodiments of the present invention, the number of carbon atoms of the (aliphatic) carboxylic acid, the (aliphatic) sodium carboxylate, or the (aliphatic) potassium carboxylate is not particularly limited, but is preferably 8 to 22, particularly preferably 11 to 18. In the third embodiment of the present invention, the number of carbon atoms in the carboxylic acid, the sodium carboxylate, or the potassium carboxylate is preferably 9 to 18, particularly preferably 11 to 18. However, if the number of carbon atoms is 8 to 10, concentration of the lithium chloride to be added needs to be significantly high for suppressing the dissolution to water of lithium carboxylate formed and increasing an amount of the crystals precipitated, in some cases. Further, if the number of carbon atoms is 19 or more, a devised procedure may be necessary such as raising a reaction temperature to 100° C. or above for complete dissolution and using urea of significantly high concentration.

If the (aliphatic) carboxylic acid is-a straight-chain saturated monocarboxylic acid, octanoic acid to docosanoic acid are preferable. Similarly, if the (aliphatic) sodium or potassium carboxylate is straight-chain saturated sodium or potassium monocarboxylate, sodium or potassium salts of octanoic acid to docosanoic acid are preferable.

Specific examples of the (aliphatic) carboxylic acid preferably used in the present invention include decanoic acid (capric acid), dodecanoic acid (lauric acid), tetradecanoic acid (myristic acid), hexadecanoic acid (palmitic acid), octadecanoic acid (stearic acid), docosanoic acid (behenic acid), oleic acid, linoleic acid, and linolenic acid. Those carboxylic acids can be used singly or in combination of two or more kinds thereof.

Similarly, specific examples of the (aliphatic) sodium or potassium carboxylate preferably used in the present invention include sodium or potassium salts of decanoic acid (capric acid), dodecanoic acid (lauric acid), tetradecanoic acid (myristic acid), hexadecanoic acid (palmitic acid), octadecanoic acid (stearic acid), docosanoic acid (behenic acid), oleic acid, linoleic acid, or linolenic acid. These (aliphatic) sodium or potassium carboxylates can be used singly or in combination of two or more kinds thereof.

In the present invention, the molar ratio of the (aliphatic) carboxylic acid (or the (aliphatic) sodium carboxylate or the (aliphatic) potassium carboxylate):water is preferably from (0.5:1,000) to (5:1,000), more preferably from (0.5:1,000) to (2:1,000).

Further, an amount of the lithium hydroxide is in a range of preferably 90 to 110 mol %, more preferably 95 to 105 mol %, to the (aliphatic) carboxylic acid. Similarly, an amount of the lithium chloride is in a range of preferably 50 to 500 mol %, to the (aliphatic) sodium carboxylate or the (aliphatic) potassium carboxylate.

In the present invention, preferably in the first and second embodiments of the present invention, when using the (aliphatic) carboxylic acid or the like having 8 to 10 carbon atoms, the lithium chloride can be further added and dissolved in water, in a ratio of 10 to 500 mol % to the (aliphatic) carboxylic acid or the like, for controlling dissolution of the lithium carboxylate to be formed in water and increasing an amount of precipitation.

Further, in the present invention, preferably in the first and second embodiments of the present invention, when using the (aliphatic) carboxylic acid having 11 or more carbon atoms, the additional lithium chloride is preferably not added, or can be added in an amount at most 100 mol % to the (aliphatic) carboxylic acid.

In the present invention, preferably in the third embodiment of the present invention, when using the carboxylic acid or the like having 9 to 11 carbon atoms, the lithium chloride is preferably further added and dissolved in water in a ratio of 0.5 to 1 mol to the carboxylic acid or the like, for controlling dissolution of the lithium carboxylate to be formed in water and increasing an amount of precipitation.

Further, in the present invention, preferably in the third embodiment of the present invention, when using the carboxylic acid having 12 carbon atoms, such as dodecanoic acid (lauric acid), the lithium chloride is preferably not added at all, or preferably added in an amount at most about 0.5 mol to the carboxylic acid. When using the carboxylic acid having 13 or more carbon atoms, the lithium chloride is preferably not added at all.

To precipitate lithium carboxylate in long fibrous form, the (aliphatic) carboxylic acid or the like must be once completely dissolved in water before the precipitation. However, when precipitating, for example, lithium laurate C₁₁H₂₃COOLi, lauric acid alone is hardly dissolved as it is. The lauric acid eventually dissolves in hot water at 98 to 100° C. by adding a small amount of the lauric acid (1 mole of the lauric acid, to 1,000 mol of water, for example). However, only scaly, plate-like, or rod-like crystals precipitate, after cooling gradually, in an aqueous solution prepared by adding equivalent mol of the lithium hydroxide alone. A large amount of long fibrous crystals precipitate in water, by slightly changing a molar ratio of the lauric acid and LiOH/H₂O, and by further adding about 2 mol of urea. A usual Fourier transform infrared spectroscopy (FTIR), for example, can confirm that the thus-obtained crystals as described above are in fact crystals of a lithium salt. Similarly, adjusting the amounts of carboxylic acid, sodium hydroxide, water and urea to be added allows preparation of a long-chain-like lithium salt in water, in the cases of various carboxylic acids having 8 to 22 carbon atoms, for example, 9 to 18 carbon atoms.

In the present invention, the amount of the urea to be added depends on a kind of the (aliphatic) carboxylic acid or the like to be used, but the urea is added in preferably 1 to 16-fold molar ratio, more preferably 2 to 8-fold molar ratio, to the (aliphatic) carboxylic acid or the like. When using stearic acid, for example, 8 to 16-fold molar ratio of the urea is preferably added. Further, when using lauric acid, 2 to 8-fold molar ratio of the urea is preferably added.

In the present invention, “gradually cooling” means that the temperature is slowly cooled down from the heated state of the system to room temperature, according to a usual cooling method. Lithium carboxylate crystals are obtained by gradually cooling from the reaction temperature to room temperature (25° C.), generally at a cooling speed of 5 to 50° C./hour, preferably 10 to 20° C./hour, after the reaction with or without stirring, though depending on a difference in crystallinity.

In the present invention, stirring can be conducted by selecting any of the methods conventionally used.

Hereinafter, two embodiments of a method of producing lithium carboxylate crystals according to the present invention are shown, but the present invention is not limited to those.

(1) Carboxylic acid (lauric acid, for example) and urea are dissolved in pure water and suspended, and then about equivalent mol of lithium hydroxide to the carboxylic acid is slowly dropped (in 30 minutes, for example), under heating and stirring. Lithium chloride is further added thereto when the carboxylic acid has short alkyl chain length. After completing the dropping, a solution temperature is slowly lowered (in 5 hours, for example) to a room temperature (25° C.) while continuously stirring. Further, the solution is left at rest at room temperature for a prescribed period of time (10 to 50 hours, for example), continuously stirring at room temperature or without stirring, as required.

For the lithium carboxylate of the present invention having 16 or less carbon atoms, the high purity crystals are generally obtained in a uniformly dispersed form in the whole water existing in a reaction vessel, regardless of the crystal form.

When long fibrous crystals are obtained, the whole content of the vessel may be in a white gel-like form with the whole water caught by the crystals. Further, the lithium carboxylate of the present invention having 17 or more carbon atoms uniformly crystallize or precipitate on an upper portion and a central portion of the water, in a dispersed form in most of the water.

The obtained crystals are filtered through a suction funnel and then washed with pure water, to completely remove urea, and in some cases lithium chloride, dissolved in water, and a trace amount of carboxylic acid and lithium hydroxide possibly remaining in water. Further, the crystals are repeatedly suspended in fresh pure water, stirred, subjected to suction filtration, and washed as required. The crystals are-then air-dried at room temperature under atmospheric pressure, generally. Finally, the crystals are dried under vacuum, and then subjected to a test to confirm purity and form of the obtained crystals. In addition, for example, usual Fourier transform infrared spectroscopy (FTIR) can confirm that the thus-obtained crystals are in fact crystals of a lithium salt.

(2) Sodium carboxylate or potassium carboxylate (sodium stearate, for example) and urea are dissolved and suspended in pure water. While heating and stirring the resultant mixture, an excess amount (2.2 equivalents, for example) of lithium chloride to the sodium carboxylate or potassium carboxylate is added. A temperature of the mixture is gradually lowered to room temperature (25° C.) while continuing stirring. Further, the mixture is left at rest at the room temperature for a prescribed period of time (two months, for example) continuing stirring at the room temperature or without stirring, as required.

The high purity crystals are generally obtained in a uniformly dispersed form in the whole water in the reaction vessel, regardless of the crystal form.

When long fibrous crystals are obtained, the whole content of the vessel may be in a white gel-like form with the whole water caught by the crystals.

Then, the thus-obtained crystals are purified in the same manner as the (1) described above.

The lithium carboxylate long fiber according to the present invention are more hydrophobic than sodium carboxylate long fibers. Further, since the precipitated long fibrous crystals are stable, the long fibrous crystals maintains a long fibrous structure, even after the crystals are removed from the water and dried up.

Use of the lithium carboxylate long fibrous crystals of the present invention allows extremely efficient adsorption, for example, of a liquid organic halogen compound such as polychlorinated biphenyl (PCB) by simply, lightly shaking the compound and the crystals at room temperature, and recovery-of the organic halogen compound as a macroscopic aggregate or mass.

The lithium carboxylate long fibrous crystals of the present invention selectively adsorb PCB by simply charging the fibrous crystals in a metal vessel polluted by the PCB, for example. To be specific, the PCB and the fibrous crystals bond and combine each other, by first adding water to the vessel containing the PCB, then adding the lithium carboxylate long fibrous crystals, and lightly shaking the vessel. If a ratio of the PCB to the lithium carboxylate long fibrous crystals is not excessive, the fibers substantially adsorb all of the PCB and sink and precipitated to the bottom of the water in the washed vessel. The lithium carboxylate long fibrous crystals having adsorbed the PCB maintain a fibrous form if the ratio of the PCB is small. If the mass ratio of the PCB reaches several folds of the lithium carboxylate long fibers, the fibers sink to the bottom of the water as a wholly, fluffy aggregate (or egg-like aggregate). This aggregate maintains solid form and can be separated from the added water by scooping from the original vessel through a usual means using a metal spoon or a glass vessel.

Examples of the liquid halogen compound which can be adhered to and recovered by the solidifying material composed of the lithium carboxylate long fibrous crystals of the present invention include: highly toxic compounds such as PCB, coplanar PCB, and dioxins; halogenated saturated hydrocarbons such as dichloromethane, 1,2-dichloroethane, 1,6-dibromohexane, perfluorohexane, 1,8-dibromooctane, and 1,10-dibromodecane; halogenated unsaturated hydrocarbons such as cis-dichloroethylene, trans-dichloroethylene, and trichloroethylene; alicyclic halogenated hydrocarbons such as chlorocyclohexane, bromocyclohexane, and fluorocyclohexane; aromatic halogenated hydrocarbons such as chlorobenzene, bromobenzene, iodobenzene, 1,2-dichlorobenzene, and trichlorobenzene. About 5 to 100 g of the halogen-containing liquid organic compound can be generally adsorbed to 1 g of the solidifying material of the present invention, though depending on a kind of the halogen-containing liquid organic compound to be collected. To allow the solidifying material of the present invention to adsorb the halogen-containing liquid organic compound, the solidifying material may be contacted with the halogen-containing liquid organic compound preferably for several seconds or more, more preferably with gentle shaking.

The liquid halogen compound can be completely adsorbed to the solidifying material by leaving at rest for some hours in some cases.

After the solidified products (solid aggregates) which have adsorbed the halogen-containing liquid organic compound are separated and recovered from the polluted water, by subsequently adding water thereto and heating, they can be separated into the respective components, i.e. the lithium carboxylate long-fibrous crystals and the recovered liquid halogen compound. The lithium carboxylate long fibers are separated and transferred to the aqueous phase, while the liquid halogen compound can be separated and recovered from the aqueous phase. A majority of the lithium carboxylate long-fibrous crystals can be used again and repeatedly for producing the lithium carboxylate long-fibrous crystals usable as the solidifying material for liquid halogen compound. Generally, heating for separation of the lithium carboxylate and the liquid halogen compound is conducted preferably at 80° C. or more.

However, many halogen compounds are preferably incinerated or the like as solidified, instead of being subjected to separation and recovering.

The solidifying material composed of the lithium carboxylate long-fibrous crystals of the present invention may preferably be used, for example, by: surrounding a periphery of a site of a leakage accident in situ such as the ocean, rivers, and lakes with an oil fence or the like; directly spreading the solidifying material; and solidifying the leaked halogen compounds for immediate recovery thereof. An amount of the solidifying material to be spread may be suitably selected depending on a kind of the halogen compound or actual conditions of the site, but is generally about 1 to 30 mass %, preferably about 5 to 20 mass % to the mass of the halogen compound.

The fixing material of the present invention adsorbs gaseous hydrocarbon selectively by, for example, only introducing gaseous hydrocarbon and then stirring gently. Unless the ratio of gaseous hydrocarbon to the lithium carboxylate long-fibrous crystals is too excessive, substantially all-gaseous hydrocarbon are adsorbed in presence of water, to float on the water. The complexes after having adsorbed the gaseous hydrocarbon are in the form of fine particle complex when the ratio of the gaseous hydrocarbon is low, while the ratio of the gaseous hydrocarbon by mass is higher by several times than the lithium carboxylate long-fibrous crystals, the complexes float on the water as a whole spherical mass or a rounding mass of fibers. The mass can be easily scooped up from the water.

The examples of the hydrocarbon being gaseous at 20° C. at 0.1 MPa, which can be solidified by the fixing material of the present invention, include n-butane, isobutane, 1-butene, cis-2-butene, trans-2-butene, 1,3-butadiene, propane, and propylene.

Further, the fixing material of the present invention can solidify hydrocarbon as it is without specific treatments including the hydrocarbon contained, for example, in exhaust gas exhausted from productive facilities of chemical factories or the hydrocarbon vaporized from liquid hydrocarbon.

Further, in the present invention, a small amount of liquid hydrocarbon may be added to facilitate adsorption and solidification of gaseous hydrocarbon. Examples of the liquid hydrocarbon that can be used include all n-paraffins ranging from n-pentane to n-hexadecane in a liquid state at 20° C. and 0.1 MPa, branched paraffins, olefins, alicyclic paraffins such as cyclohexane and the like, aromatic hydrocarbons such as benzene, toluene, xylene and the like, and mixed hydrocarbons such as light oil, kerosene, liquid paraffin and the like. Taking easiness in handling, decomposition and recovery after fixation into consideration, unstable olefins and mixed hydrocarbons need not be used, and paraffin-series hydrocarbons, alicyclic paraffins and aromatic hydrocarbons, each having a relatively simple and stable structure, can be used.

Depending on the type of gaseous hydrocarbon to be solidified, in the case of only a gaseous hydrocarbon, generally, 1 part by mass of the fixing material of the present invention can adsorb the gaseous hydrocarbon in an amount of about 1 to 100 parts by mass. Further, in the case of the combination of a gaseous hydrocarbon with a liquid hydrocarbon, generally, 1 part by mass of the fixing material of the present invention can adsorb the gaseous hydrocarbon in an amount of about 5 to 50 parts by mass. In the latter case, the thus-solidified gaseous hydrocarbon becomes much more stale, as compared with the solidified gaseous hydrocarbon obtained from the gaseous hydrocarbon alone in the former case.

To allow the fixing material of the present invention to adsorb and solidify a gaseous hydrocarbon, the fixing material may be contacted with the gaseous hydrocarbon preferably for 1 minute or more, more preferably with gentle shaking.

Generally, the solid aggregates formed after solidifying only a gaseous hydrocarbon have a slightly higher vapor pressure than the atmospheric pressure, and is thus preferably stored in a sealed container. Accordingly, to obtain the original gaseous hydrocarbon, the solidified complexes may be released at ordinary temperature at atmospheric pressure, to recover the gaseous hydrocarbon in a usual method.

Generally, the solidified aggregates formed after solidifying a gaseous hydrocarbon together with a liquid hydrocarbon have a lower vapor pressure than the atmospheric pressure, so it is not always necessary to store the solid aggregates in a sealed container, but for securing safety, the aggregates are also preferably stored in a simple sealed container. Accordingly, in this case, to obtain the original gaseous hydrocarbon, the solidified aggregates may be heated to about 40 to 60° C., to release the gaseous hydrocarbon under atmospheric pressure to recover in a usual method.

On the other hand, lithium carboxylate crystals (long fibers) separated from the hydrocarbon and recovered following the above procedure, may be used for producing lithium carboxylate long-fibrous crystals that can be used to constitute the fixing material for a gaseous hydrocarbon, and that can be used repeatedly.

The high-purity lithium carboxylate crystals of the present invention are useful as metal soaps widely used for various applications such as a lubricant, a slip additive, a thickener, and a releasing agent, in various industrial fields such as plastics, paper and pulp, grease, metallurgy, casting, paint, rubber industry, and ceramics. Further, the high-purity lithium carboxylate crystals of the present invention change to the most stable, long fibrous crystals in many cases, and the crystals once in a long-fiber form do not change the form and can be stored for a long period of time, even after dried up.

Further, according to the production method for the lithium carboxylate crystal of the present invention, the high-purity lithium carboxylate crystals can be industrially obtained with high yield.

The solidifying material composed of lithium carboxylate long-fibrous crystals of the present invention can efficiently solidify a liquid halogen-containing organic compound through a physicochemical method. The solidifying material of the present invention is composed of stable, long fibrous crystals, and thus, does not change its long fiber form, allowing storage for a long period of time.

Further, according to the inventive method of solidifying a halogen-containing liquid organic compound, it is possible to wash, capture, solidify, and recover even the halogen-containing liquid organic compound slightly remained.

Furthermore, according to the present invention, it is possible to provide a method of efficiently solidifying the gaseous hydrocarbons through a physicochemical method.

According to the fixing material of the present invention, a hydrocarbon that is gaseous at 20° C. and 0.1 MPa can be easily solidified, without damaging, for example, reactors in a factory. Further, original hydrocarbon can easily be recovered from the solidified aggregates, and the recovered fixing material can be used through recycling. Further, the fixing material of the present invention is relatively stable, chemically. In addition, the fixing material is a safe and harmless substance, and even if the material flows out of the reactors and is hardly recovered, the material itself is least dangerous affecting to the living things in the environment and to the environment.

Further, the fixing material of the present invention has exceptional gaseous hydrocarbon collecting ability, and stably collects a large amount of hydrocarbon. The fixing material dispersed in water quite stably retains such functions for a long period of time. In addition, the dried fixing material has stable crystals, allowing retention of high collecting ability of the hydrocarbon.

The present invention will be described in more detail based on the following examples, but the present invention is not limited thereto.

### EXAMPLES

### Example 1

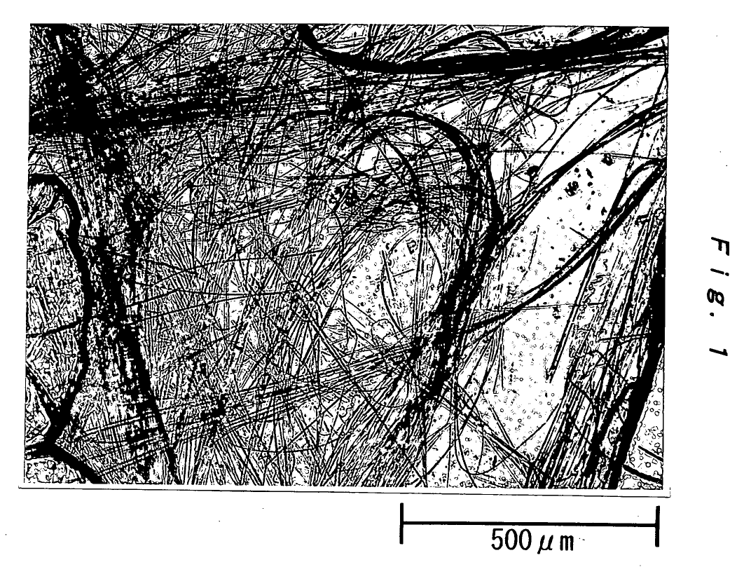

8.01 g (0.04 mol) of lauric acid (n-dodecanoic acid, n-C₁₁H₂₃COOH), 9.61 g (0.16 mol) of urea ((NH₂)₂CO), and 330 g of pure water were placed in a 500-ml Pyrex (trademark) four-necked flask, and the mixture was heated using an oil bath (bath temperature was 116° C. and temperature of the aqueous solution in the flask was 95° C.). While stirring the solution at 250 rpm using a stainless-steel stirring blade, an aqueous solution containing 1.68 g (0.04 mol) of lithium hydroxide monohydrate (LiOH.H₂O) dissolved in 30 g of pure water was slowly dropped into the solution in about 30 minutes. An amount of the pure water after completing the dropping reached 360 g (20 mol). The lauric acid completely dissolved in the water as the lithium hydroxide was dropped. A large volume of bubbles generated, and the aqueous solution turned clear and colorless. During this period, the solution temperature gradually raised to reach 100° C. and became constant. The solution was further continuously stirred, maintaining 100° C., for ripening. At this time, lithium laurate was probably synthesized quantitatively and completely dissolved in water. The volume of the bubbles generated gradually decreased, but a state of the clear and colorless aqueous solution did not change at all. The heater was turned off after two hours, and the solution was gradually cooled to room temperature (25° C.), stirring at a speed of 6 rpm. 30 minutes after the start of cooling, precipitation of crystals began at 83° C., and almost all precipitated by 80° C. The whole content was in a uniform, white gel-like form with the whole water in the reaction vessel caught by long fibrous crystals mutually intertwined. FIG. 1 shows an optical microphotograph (objective lens magnification of 10 ) of the thus-obtained long-fibrous crystals. Each long fiber was not a single crystal but had a long and continuous structure with assembled extremely fine and short fibers. Thickness of one long fiber was about 2 to 4 μm, and length thereof was about 100 to 2,000 μm. The long-fibrous crystals and the aqueous solution could be easily separated through suction filtration. The crystals were further washed with pure water, and the filtrate was separated to separate and remove a trace amount of the lauric acid, the lithium hydroxide, and the urea remaining in the solution. The crystals were then dried under vacuum, to isolate high purity lithium laurate crystals alone (6.5 g, 80% yield). The long-fibrous crystals were confirmed to remain stable at room temperature (25° C.), over several months, even after drying under vacuum as described above. Results of elemental analysis confirmed that the crystals had about 97.6% purity and the remaining 2.4% was urea. Further, infrared spectroscopy measurement confirmed that lauric acid, which was a raw material, was not remained in the crystals.

In a system not adding urea, an aggregated precipitate immediately formed similarly to synthetic methods conventionally conducted, and no long fibrous crystals could be obtained.

### Example 2

4.57 g (0.02 mol) of myristic acid (n-tetradecanoic acid, n-C₁₃H₂₇COOH), 4.81 g (0.08 mol) of urea ((NH₂)₂CO), and 330 g of pure water were placed in a 500-ml Pyrex four-necked flask, and the mixture was heated using an oil bath (bath temperature was 125° C. and temperature of the aqueous solution in the flask was 90° C.). While stirring the solution at 250 rpm using a stainless-steel stirring blade, an aqueous solution containing 0.84 g (0.02 mol) of lithium hydroxide monohydrate (LiOH.H₂O) dissolved in 30 g of pure water was slowly dropped into the solution in about 20 minutes. An amount of the pure water after completing the dropping reached 360 g (20 mol). The aqueous solution turned blue-white/pale blue and translucent as the lithium hydroxide was dropped. This implies that myristic acid and lithium myristate in formation were dissolved not completely in the water and were dispersed in a colloidal form. Bubbles generated simultaneously. The solution temperature became constant at about 100° C. after the completion of the dropping. A volume of the bubbles generated increased, and the solution turned pale grayish white. The solution was further continuously stirred, maintaining 100° C., for ripening. By this stage, lithium myristate was probably synthesized quantitatively and gradually dissolved in the water. The volume of the bubbles generated was still large, but the color of the solution returned to white-blue and translucent. The heater was turned off after two hours, and the solution was gradually cooled to room temperature (25° C.), stirring at 6 rpm. Soon after the start of cooling, precipitation of crystals began at as early as 98° C. The crystals precipitated at this time were clear and plate-like or rod-like, but the whole content was in a uniform, white liquid form with the whole water in the reaction vessel moderately caught by the crystals. The crystals kept at the room temperature for half a month gradually changed to long-fibrous crystals, and then the long-fibrous form remained stable thereafter. Along with the above, the whole reaction liquid changed from a liquid form to a gel form.

The crystals were then washed and dried in the same manner as the lithium laurate in Example 1, to obtain long-fibrous lithium myristate of about 98% purity (3.7 g, 80% yield). Thickness of one long fiber was about 2 to 3 μm, and length thereof was about 300 to 2,000 μm.

### Example 3

1.423 g (0.005 mol) of stearic acid (n-octadecanoic acid, n-C₁₇H₃₅COOH), 4.81 g (0.08 mol) of urea ((NH₂)₂CO), and 150 g of pure water were placed in a 500-ml Pyrex four-necked flask, and the mixture was heated using an oil bath (bath temperature was 118° C. and temperature of the aqueous solution in the flask was 95° C.). While stirring the solution at 300 rpm using a stainless stirring blade, an aqueous solution containing 0.210 g (0.005 mol) of lithium hydroxide monohydrate (LiOH.H₂O) dissolved in 30 g of pure water was slowly dropped into the solution in about 20 minutes. An amount of the pure water after completing the dropping reached 180 g (10 mol). The aqueous solution turned blue-white and translucent as the lithium hydroxide was dropped. This implies that stearic acid and lithium stearate in formation were dissolved not completely in the water and were dispersed in a colloidal form. Bubbles generated simultaneously. The solution temperature became constant at about 100° C. after the completion of the dropping. A volume of the bubbles generated increased. The solution was further continuously stirred, maintaining 100° C., for ripening. By this stage, lithium stearate was probably synthesized quantitatively and gradually dissolved in the water. The volume of the bubbles generated was still large. The color of the solution remained white-blue and translucent. The heater was turned off after 70 minutes, and the solution was gradually cooled to room temperature (25° C.), stirring at 100 rpm. 30 minutes after the start of cooling, precipitation of white, cotton-like crystals began at 78° C. The crystals gradually changed to plate-like or flock-like. A part of water liberated down below separated, while most of the water in the reaction vessel was moderately caught by the crystals. The crystals kept at the room temperature for half a month or longer gradually changed to long-fibrous to cotton-like crystals, and then the short fibrous form remained stable thereafter. The state was still maintained in that a small amount of the water liberated down below, while the most of the reaction solution was caught by the crystals.

The crystals were then washed and dried in the same manner as the lithium laurate in Example 1, to obtain short-fibrous lithium stearate of about 98% purity (1.16 g, 80% yield). Thickness of one short fiber was about 2 to 3 μm, and length thereof was about 100 to 500 μm.

### Example 4

1.58 g (0.01 mol) of nonanoic acid (n-C₈H₁₇COOH), 1.20 g (0.02 mol) of urea ((NH₂)₂CO), and 150 g of pure water were placed in a 500-ml Pyrex four-necked flask, and the mixture was heated using an oil bath (bath temperature was 112° C. and temperature of the aqueous solution in the flask was 95° C.). While stirring the solution at 300 rpm using a stainless stirring blade, an aqueous solution containing 0.420 g (0.01 mol) of lithium hydroxide monohydrate (LiOH.H₂O) dissolved in 30 g of pure water was slowly dropped into the solution in about 20 minutes. An amount of the pure water after completing the dropping reached 180 g (10 mol). The solution was clear and colorless and bubbles were not generated after completing the dropping of the lithium hydroxide, implying that the components were completely dissolved in water. The heater was turned off after 3.5 hours, and the solution was gradually cooled, but precipitation of crystals was hardly observed even at 46° C. Therefore, lithium chloride was successively added, to finally reach 4.24 g (0.1 mol). The solution was heated again for complete dissolution, and after the solution turned clear and colorless, the heater was turned off again for gradual cooling. Precipitation of crystals began when the solution temperature reached 49° C., and the crystals precipitated as scaly crystals.

The crystals were then washed and dried in the same manner as the lithium laurate in Example 1, to obtain 0.5 g of scaly lithium nonanate of about 98% purity (95% yield). A size of one scale was about 50 μm×100 μm.

### Example 5

2.22 g (0.01 mol) of sodium laurate (sodium n-dodecanoate, n-C₁₁H₂₃COONa), 0.60 g (0.01 mol) of urea ((NH₂)₂CO), and 165 g of pure water were placed in a 500-ml Pyrex four-necked flask, and the mixture was heated using an oil bath (bath temperature was 120° C. and temperature of an aqueous solution in the flask was 94° C.). The sodium laurate immediately dissolved in water completely. While stirring the solution at 250 rpm using a stainless stirring blade, an aqueous solution containing 0.42 g (0.01 mol) of lithium chloride (LiCl) dissolved in 15 g of pure water was slowly dropped into the solution in about 5 minutes. An amount of the pure water after completing the dropping reached 180 g (10 mol). The aqueous solution was clear and colorless before and after the dropping of the lithium chloride. The heater was turned off immediately, and the solution was gradually cooled to room temperature (25° C.), stirring at 5 rpm. 40 minutes after the start of cooling, precipitation of crystals began at 70° C. Particulate fine crystals gradually changed to needle crystals and tabular crystals after leaving at rest at room temperature. The crystals gradually changed to not very long fibrous crystals and became stable, by further leaving at rest for several days.

The crystals were then washed and dried in the same manner as the lithium laurate in Example 1, to obtain 2.0 g of short fibrous lithium laurate of about 98% purity (90% yield). Thickness of one short fiber was about 2 to 4 μm, and length thereof was about 100 to 500 μm.

### Example 6

1.53 g (0.005 mol) of sodium stearate (sodium n-octadecanoate, n-C₁₇H₃₅COONa), 4.80 g (0.04 mol) of urea ((NH₂)₂CO), and 150 g of pure water were placed in a 500-ml Pyrex four-necked flask, and the mixture was heated using an oil bath (bath temperature was 120° C. and temperature of an aqueous solution in the flask was 75° C.). While stirring the solution at 250 rpm using a stainless stirring blade, an aqueous solution containing 0.23 g (0.011 mol) of. lithium chloride (LiCl) dissolved in 30 g of pure water was slowly dropped into the solution in about 5 minutes. An amount of the pure water after completing the dropping reached 180 g (10 mol). The aqueous solution turned white-blue and opaque, after the dropping of the lithium chloride. A solution temperature was gradually raised to 99° C., and stirring was continued. The aqueous solution turned white-blue and translucent, and a large volume of bubbles generated. The heater was turned off after 2 hours, and the solution was gradually cooled to room temperature (25° C.), while stirring at 10 rpm. 20 minutes after the start of cooling, precipitation of crystals began at 90° C. from water surface. Cloud-like to cotton-like fine crystals gradually changed to long-fibrous crystals, by leaving at rest at the room temperature (25° C.) for about 2 months, and the crystals became stable.

The crystals were then washed and dried in the same manner as the lithium laurate of Example 1, to obtain quantitatively long-fibrous lithium stearate of about 98% purity (1.2 g, 80% yield). Thickness of one long fiber was about 2 to 4 μm, and length thereof was about 100 to 1,000 μm.

### Example 7

18 g of pure water and 500 mg of lithium laurate long fibers obtained in the above Example 1 were placed in a 60-ml pressure-tight glass test tube, and 2.98 g of 1,2-dichlorobenzene was added thereto. Light shaking immediately resulted in firm white aggregates which sunk to the bottom of the water. At this time, a small amount of oil droplets adhered to an inner wall of the pressure-tight, glass test tube was first observed. Light shaking by tilting the glass tube so that the adhered portion came in contact with the white aggregates immediately resulted in incorporation of the oil droplets into the white aggregates and a clean inner wall. The water was slightly cloudy. Further, minute amounts of 1,2-dichlorobenzene as oil droplets were observed floating on water surface, but those were also immediately incorporated into the white aggregates by bringing the droplets in contact with the white aggregates. Leaving the test tube at rest as it was at room temperature (25° C.) for about 2 hours resulted in completely clear and colorless water. The water remained completely clear and colorless even after further shaking. Any Peaks were not detected at all, except for a peak derived from phase transformation of water, when analyzing the resulting water portion using a differential scanning calorimeter. The results confirmed that the lithium laurate and the 1,2-dichlorobenzene were completely incorporated into the white aggregates within a detection limit of the differential scanning calorimeter. On the other hand, the white aggregates were confirmed to contain a small amount of the water (several percents in term of mass), in addition to the lithium laurate and the 1,2-dichlorobenzene.

### Example 8

Placing 18 g of pure water in a pressure-tight, glass test tube and adding 3.0 g of 1,2-dichlorobenzene thereto resulted in that the 1,2-dichlorobenzene sunk as a liquid at the bottom of the water. Then, after adding thereto 500 mg of lithium laurate long fibers obtained in Example 1, the lithium laurate long fibers remained floating on the water surface. However, light shaking of the test tube resulted in immediate formation of firm white aggregates which sunk to the bottom of the water. The same results as that in Example 7 were obtained regarding cloudiness of the water, progress afterwards, and analysis using a differential scanning calorimeter.

In other words, reversing the adding order with the above Example 7 brought the same results.

### Example 9

Similar to Example 7, solidification of 1.51 g of biphenyl (solid white crystals at room temperature, 25° C.) was attempted, using 18 g of pure water and 500 mg of lithium laurate long fibers. However, the lithium laurate long fibers and the biphenyl crystals both dispersed in the pure water to provide a uniform dispersion as a whole, thereby not allowing solidification. Further, adding thereto 1.83 g of 1,2-dichlorobenzene and lightly shaking immediately resulted in firm white aggregates which sunk to the bottom of the water. The water was slightly cloudy. Leaving the test tube at rest as it was at room temperature (25° C.) for about 2 hours resulted in completely clear and colorless water. The water remained completely clear and colorless, even after further shaking. Further, the white aggregates appeared the same as in the case using the 1,2-dichlorobenzene alone. Peaks other than a phase transformation peak of pure water were not detected at all when analyzing the resultant water portion using a differential scanning calorimeter. The results confirmed that the lithium laurate, biphenyl, and 1,2-dichlorobenzene were completely incorporated into the white aggregates, within a detection limit of the differential scanning calorimeter.

### Example 10

In the same manner as in Example 7, solidification experiments were conducted for about 3 to 8 g, respectively, of pure chlorobenzene, bromobenzene, iodobenzene, dichloromethane, 1,2-dichloroethane, hexafluorobenzene, perfluorohexane, 1,6-dibromohexane, 1,8-dibromooctane, 1,10-dibromodecane, trichloromethane (chloroform), tribromomethane (bromoform), 1,2-dichloroethylene, and trichloroethylene, by placing 18 g of pure water and 500 mg of lithium laurate long fibers in a 60-ml pressure-tight glass test tube, to obtain the same results.

### Example 11

A pressure-tight glass vessel, whose capacity was 60 mL, in which 100 mg of the lithium laurate long-fibrous crystals obtained in the above Example 1 (those crystals were used as a fixing material in Example 11) and 18 g of pure water were placed, was cooled to −30° C. Added was 300 mg of 1-butene to the vessel from a gaseous cylinder, and the vessel was sealed hermetically. The temperature of the vessel was returned to room temperature, and the vessel was lightly shaken, resulting in an immediate solidification of the 1-butene.

### Example 12

The solidification was conducted in the same manner as in Example 11, except that n-butane, 1,3-butadiene, trans-2-butene, propylene, or propane was used instead of 1-butene. The solidification of each of these gaseous hydrocarbons was confirmed, respectively.

Having described our invention as related to the present embodiments, it is our intention that the invention not be limited by any of the details of the description, unless otherwise specified, but rather be construed broadly within its spirit and scope as set out in the accompanying claims.

1. A lithium carboxylate crystal, which is obtained by: dissolving an aliphatic carboxylic acid, lithium hydroxide, and urea in water, to give a solution thereof; and crystallizing lithium carboxylate from the solution.

2. The lithium carboxylate crystal according to claim 1, wherein the lithium carboxylate crystal has high purity.

3. A lithium carboxylate crystal, which is obtained by: dissolving an aliphatic carboxylic acid, lithium hydroxide, urea, and lithium chloride in water, to give a solution thereof; and crystallizing lithium carboxylate from the solution.

4. The lithium carboxylate crystal according to claim 3, wherein the lithium carboxylate crystal has high purity.

5. A lithium carboxylate crystal, which is obtained by: dissolving at least one carboxylate selected from the group consisting of aliphatic sodium carboxylates and aliphatic potassium carboxylates, lithium chloride, and urea in water, to give a solution thereof; and crystallizing lithium carboxylate from the solution.

6. The lithium carboxylate crystal according to claim 5, wherein the lithium carboxylate crystal has high purity.

7. A method of producing a lithium carboxylate crystal, comprising the steps of:
dissolving an aliphatic carboxylic acid, lithium hydroxide, and urea in water, to give a solution thereof; and
crystallizing lithium carboxylate from the solution.

8. The method according to claim 7, wherein the lithium carboxylate crystal has high purity.

9. The method according to claim 7, wherein, in the dissolving step, lithium chloride is added in the water, to dissolve the aliphatic carboxylic acid, lithium hydroxide, and urea.

10. The method according to claim 9, wherein the lithium carboxylate crystal has high purity.

11. A method of producing a lithium carboxylate crystal, comprising the steps of:
dissolving at least one carboxylate selected from the group consisting of aliphatic sodium carboxylates and aliphatic potassium carboxylates, lithium chloride, and urea in water, to give absolution thereof; and
crystallizing lithium carboxylate from the solution.

12. The method according to claim 11, wherein the lithium carboxylate crystal has high purity.

13. A solidifying material for a halogen-containing liquid organic compound, comprising lithium carboxylate long-fibrous crystals;
wherein the lithium carboxylate long-fibrous crystals are obtained by: dissolving an aliphatic carboxylic acid, lithium hydroxide, and urea in water, to give a solution thereof; and crystallizing lithium carboxylate from the solution.

14. A method of solidifying a halogen-containing liquid organic compound, comprising:
solidifying the halogen-containing liquid organic compound, by using the solidifying material according to claim 13.

15. A solidifying material for a halogen-containing liquid organic compound, comprising lithium carboxylate long-fibrous crystals;
wherein the lithium carboxylate long-fibrous crystals are obtained by: dissolving an aliphatic carboxylic acid, lithium hydroxide, urea, and lithium chloride in water, to give a solution thereof; and crystallizing lithium carboxylate from the solution.

16. A method of solidifying a halogen-containing liquid organic compound, comprising:
solidifying the halogen-containing liquid organic compound, by using the solidifying material according to claim 15.

17. A solidifying material for a halogen-containing liquid organic compound, comprising lithium carboxylate long-fibrous crystals;
wherein the lithium carboxylate long-fibrous crystals are obtained by: dissolving at least one carboxylate selected from the group consisting of aliphatic sodium carboxylates and aliphatic potassium carboxylates, lithium chloride, and urea in water, to give a solution thereof; and crystallizing lithium carboxylate from the solution.

18. A method of solidifying a halogen-containing liquid organic compound, comprising:
solidifying the halogen-containing liquid organic compound, by using the solidifying material according to claim 17.

19. A fixing material for a hydrocarbon that is gaseous at 20° C. and 0.1 MPa,
wherein the fixing material is obtained by the steps of: dissolving a carboxylic acid, lithium hydroxide, and urea in water, to give a solution; gradually cooling the solution; and precipitating crystals in a long fibrous shape from the solution.

20. The fixing material according to claim 19, wherein the precipitated long-fibrous crystals are dried up.

21. The fixing material according to claim 19, wherein the carboxylic acid is an aliphatic carboxylic acid.

22. The fixing material according to claim 19, wherein the fixing material is obtained by further dissolving lithium chloride in the water, in the dissolving step.

23. The fixing material according to claim 22, wherein the precipitated long-fibrous crystals are dried up.

24. A fixing material for a hydrocarbon that is gaseous at 20° C. and 0.1 MPa,
wherein the fixing material is obtained by the steps of: completely dissolving at least one carboxylate selected from the group consisting of sodium carboxylates and potassium carboxylates, and urea in water, to give a solution; adding, to the solution, an aqueous lithium chloride solution; gradually cooling the solution; and precipitating crystals in a long fibrous shape from the solution.

25. The fixing material according to claim 24, wherein the precipitated lohg-fibrous crystals are dried up.

26. The fixing material according to claim 24, wherein the carboxylate is an aliphatic carboxylate.

27. A method of solidifying a hydrocarbon that is gaseous at 20° C. and 0.1 MPa, comprising:
solidifying the hydrocarbon, by using the fixing material according to claim 19.

28. A method of solidifying a hydrocarbon that is gaseous at 20° C. and 0.1 MPa, comprising:
solidifying the hydrocarbon, by using the fixing material according to claim 22.

29. A method of solidifying a hydrocarbon that is gaseous at 20° C. and 0.1 MPa, comprising:
solidifying the hydrocarbon, by using the fixing material according to claim 24.

30. A method of solidifying a hydrocarbon that is gaseous at 20° C. and 0.1 MPa, comprising the steps of:
solidifying the hydrocarbon, by using the fixing material according to claim 19, to give a solid aggregate;
heating the solid aggregates, to decompose into lithium carboxylate crystals and the gaseous hydrocarbon;
separating the lithium carboxylate crystals from the gaseous hydrocarbon; and
recovering the lithium carboxylate crystals for recycling.

31. A method of solidifying a hydrocarbon that is gaseous at 20° C. and 0.1 MPa, comprising the steps of:
solidifying the hydrocarbon, by using the fixing material according to claim 22, to give a solid aggregate;
heating the solid aggregates, to decompose into lithium carboxylate crystals and the gaseous hydrocarbon;
separating the lithium carboxylate crystals from the gaseous hydrocarbon; and
recovering the lithium carboxylate crystals for recycling.

32. A method of solidifying a hydrocarbon that is gaseous at 20° C. and 0.1 MPa, comprising the steps of:
solidifying the hydrocarbon, by using the fixing material according to claim 24, to give a solid aggregate;
heating the solid aggregates, to decompose into lithium carboxylate crystals and the gaseous hydrocarbon;
separating the lithium carboxylate crystals from the gaseous hydrocarbon; and
recovering the lithium carboxylate crystals for recycling.

33. A method of producing a fixing material for a hydrocarbon that is gaseous at 20° C. and 0.1 MPa, comprising the steps of:
dissolving a carboxylic acid, lithium hydroxide, and urea in water, to give a solution;
gradually cooling-the solution; and
precipitating crystals in a long fibrous shape from the solution.

34. The method according to claim 33, wherein the carboxylic acid is an aliphatic carboxylic acid.

35. The method according to claim 33, wherein the fixing material is obtained by further dissolving lithium chloride in the water, in the dissolving step.

36. A method of producing a fixing material for a hydrocarbon that is gaseous at 20° C. and 0.1 MPa, comprising the steps of:
completely dissolving at least one carboxylate selected from the group consisting of sodium carboxylates and potassium carboxylates, and urea in water, to give a solution;
adding, to the solution, an aqueous lithium chloride solution;
gradually cooling the solution; and
precipitating crystals in a long fibrous shape from the solution.

37. The method according to claim 36, wherein the carboxylate is an aliphatic carboxylate.
